(19) United States
(12) Patent Application Publication
(10) Pub. No.: US 2022/0108978 A1
(43) Pub. Date: Apr. 7, 2022

(54) Carrier Film And Apparatus And Method For Repairing LED Display Panel

(71) Applicant: V Technology Co., Ltd., Yokohama-shi (JP)

(72) Inventors: Koichi Kajiyama, Yokohama-shi (JP); Takafumi Hirano, Yokohama-shi (JP); Yoshikatsu Yanagawa, Yokohama-shi (JP)

(73) Assignee: V Technology Co., Ltd., Yokohama-shi (JP)

(21) Appl. No.: 17/285,034

(22) PCT Filed: Jul. 29, 2019
(86) PCT No.: PCT/JP2019/029667

§ 371 Date: Dec. 20, 2021

(30) Foreign Application Priority Data
Oct. 15, 2018 (JP) 2018-194651

(51) Int. Cl. H01L 25/075; H01L 21/67; H01L 21/683; H01L 33/50

(52) U.S. Cl. CPC H01L 25/0753; H01L 21/67132; H01L 21/6835; H01L 21/67253; H01L 2221/68354; H01L 2933/0041; H01L 33/50

(57) ABSTRACT

The present invention comprises a plurality of repair devices (3) that are arranged on a support film (2), each of which has a repair element in an opening (7) that is surrounded by a light shielding wall (6) for repairing a defective pixel (21) on a full-color LED display panel.

### TECHNICAL FIELD

The present invention relates to a technology for repairing defective pixels on a full-color LED display panel, and in particular, relates to a carrier film capable of consistently repairing defective pixels, and relates to an apparatus and to a method for repairing an LED display panel.

### BACKGROUND ART

Conventionally, this type of repair method includes a step of arranging a plurality of LEDs side-by-side on an element-mounting substrate that is made of a resin film, a step of transferring the LED on the element-mounting substrate onto an LED substrate, a step of detecting the unmounted portion of the LED on the LED substrate, and a repair step of selectively retransferring the LED from the element-mounting substrate to the detected unmounted portion of the LED substrate (see, for example, Patent Document 1).

### REFERENCE DOCUMENT LIST

### Patent Document

Patent Document 1: JP2009-094181 A

### SUMMARY OF THE INVENTION

### Problem to be Solved by the Invention

However, such conventional repair method transfers the LED by directly pressing it against the unmounted portion of the LED substrate, and thus, if the LED is extremely small, such as a micro-LED, the contact area of the LED on the LED substrate is small and the contact with the LED substrate may be unstable. That is, if the pressing point of the LED is somehow shifted, the LED may be tilted and contact between the wiring of the LED substrate and the electrodes of the LED may become poor.

In view of this problem, an object of the present invention is to provide a carrier film capable of consistently repairing defective pixels, and an apparatus and a method for repairing an LED display panel.

### Means for Solving the Problem

In order to achieve the above object, a carrier film according to the present invention comprises a plurality of repair devices that are arranged on a support film, and each of which has a repair element in an opening that is surrounded by a light shielding wall for repairing defective pixels on a full-color LED display panel.

Furthermore, a method for repairing an LED display panel according to the present invention uses a carrier film to repair defective pixels, wherein the carrier film has a plurality of repair devices that are arranged on a support film, and each of which has a repair element in an opening surrounded by a light shielding wall for repairing the defective pixels on the full-color LED display panel, the method comprises the steps of: a first step of removing a defective element corresponding to a defective pixel from the full-color LED display panel; a second step of joining one of the repair devices on the carrier film to the defective pixel; and a third step of peeling the support film off from the one of the repair devices that is joined to the defective pixel.

Furthermore, an apparatus for repairing an LED display panel according to the present invention comprises: a stage on which a full-color LED display panel to be repaired is mounted, wherein the stage moves in a two-dimensional plane that is parallel to a panel surface of the full-color LED display panel, and rotates around a central axis perpendicular to the panel surface; an objective lens arranged such that an optical axis is perpendicular to the mounting surface of the stage; a carrier film that includes a plurality of repair devices that are arranged on a support film, wherein each repair device has a repair element for repairing defective pixels on the full-color LED display panel to be repaired, the repair element is placed in an opening that is surrounded by a light shielding wall, and the carrier film is moved between the stage and the objective lens while the repair devices face the stage; a transparent pressure head arranged between the objective lens and the carrier film, wherein the pressure head pushes down the carrier film to press one of the repair devices against the defective pixel on the full-color LED display panel to be repaired; and an observation camera provided at one end opposite from the stage of the optical path passing through the objective lens for observing the panel surface.

### Effects of the Invention

According to the present invention, since the repair device has the repair element in the opening surrounded by the light shielding wall, a larger contact area can be obtained between the full-color LED display panel and the defective pixel as compared to the conventional art, and a stable contact between the repair device and the defect pixel can be ensured. Therefore, the defective pixel can be consistently repaired.

### BRIEF DESCRIPTION OF THE DRAWINGS

FIG. 1A is a center line cross-sectional view illustrating an embodiment of a carrier film according to the present invention.

FIG. 1B is a perspective view illustrating the embodiment of the carrier film according to the present invention.

FIG. 2A is a view of a structure of a repair device, and more specifically, is a plan view of a pixel element for repair in which three colors of LEDs are arranged.

FIG. 2B is a view of the structure of the repair device, more specifically of a subpixel element for repair in which one LED of corresponding color is arranged.

FIG. 2C is a vertical cross-sectional view of FIGS. 2A and 2B.

FIG. 3A is a view of another structure of the repair device, more specifically is a plan view of a pixel element for repair in which three colors of fluorescent layers are arranged.

FIG. 3B is a view of another structure of the repair device, and more specifically of a sub-pixel element for repair in which one fluorescent layer of corresponding color is arranged.

FIG. 3C is a vertical cross-sectional view of FIGS. 3A and 3B.

FIG. 4A is a view of still another structure of the repair device, and more specifically, is a plan view of a pixel element for repair in which three colors of fluorescent layers and LEDs that emit light in an ultraviolet or blue wavelength band are arranged.

FIG. 4B is a view of still another structure of the repair device, more specifically of a sub-pixel element for repair in which one fluorescent layer of corresponding color and one LED are arranged.

FIG. 4C is a vertical cross-sectional view of FIGS. 4A and 4B.

FIG. 5A is an explanatory view illustrating the manufacture of the carrier film according to the present invention, and more specifically, is a plan view illustrating the first half process of the first embodiment.

FIG. 5B is an explanatory view illustrating the manufacture of the carrier film according to the present invention, and more specifically, is a plan view illustrating the first half process of the first embodiment.

FIG. 5C is an explanatory view illustrating the manufacture of the carrier film according to the present invention, and more specifically a plan view illustrating the first half process of the first embodiment.

FIG. 5D is an explanatory view illustrating the manufacture of the carrier film according to the present invention, and more specifically, is a plan view illustrating the first half process of the first embodiment.

FIG. 5E is an explanatory view illustrating the manufacture of the carrier film according to the present invention, and more specifically, is a plan view illustrating the first half process of the first embodiment.

FIG. 5F is an explanatory view illustrating the manufacture of the carrier film according to the present invention, and more specifically, is a plan view illustrating the first half process of the first embodiment.

FIG. 5G is an explanatory view illustrating the manufacture of the carrier film according to the present invention, and more specifically, is a plan view illustrating the first half process of the first embodiment.

FIG. 5H is an explanatory view illustrating the manufacture of the carrier film according to the present invention, and more specifically, is the first half process of the first embodiment.

FIG. 6A is a cross-sectional view of FIG. 5A.

FIG. 6B is a cross-sectional view of FIG. 5B.

FIG. 6C is a cross-sectional view of FIG. 5C.

FIG. 6D is a cross-sectional view of FIG. 5D.

FIG. 6E is a cross-sectional view of FIG. 5E.

FIG. 6F is a cross-sectional view of FIG. 5F.

FIG. 6G is a cross-sectional view of FIG. 5G.

FIG. 6H is a cross-sectional view of FIG. 5H.

FIG. 7A is a plan view illustrating an intermediate product of the repair device that is manufactured in the first half process of the first embodiment.

FIG. 7B is a cross-sectional view taken along line A-A of FIG. 7A.

FIG. 8A is an explanatory view illustrating the manufacture of the carrier film according to the present invention, and more specifically, is a plan view illustrating the second half process of the first embodiment.

FIG. 8B is an explanatory view illustrating the manufacture of the carrier film according to the present invention, and more specifically, is a plan view illustrating the second half process of the first embodiment.

FIG. 8C is an explanatory view illustrating the manufacture of the carrier film according to the present invention, and more specifically, is a plan view illustrating the second half process of the first embodiment.

FIG. 8D is an explanatory view illustrating the manufacture of the carrier film according to the present invention, and more specifically, is a plan view illustrating the second half process of the first embodiment.

FIG. 9A is a cross-sectional view of FIG. 8A.

FIG. 9B is a cross-sectional view of FIG. 8B.

FIG. 9C is a cross-sectional view of FIG. 8C.

FIG. 9D is a cross-sectional view of FIG. 8D.

FIG. 10A is an explanatory view illustrating the manufacture of the carrier film according to the present invention, and more specifically, is a plan view illustrating the first half process of the second embodiment.

FIG. 10B is an explanatory view illustrating the manufacture of the carrier film according to the present invention, and more specifically, is a plan view illustrating the first half process of the second embodiment.

FIG. 10C is an explanatory view illustrating the manufacture of the carrier film according to the present invention, and more specifically, is a plan view illustrating the first half process of the second embodiment.

FIG. 10D is an explanatory view illustrating the manufacture of the carrier film according to the present invention, and more specifically, is a plan view illustrating the first half process of the second embodiment.

FIG. 11A is a cross-sectional view of FIG. 10A.

FIG. 11B is a cross-sectional view of FIG. 10B.

FIG. 11C is a cross-sectional view of FIG. 10C.

FIG. 11D is a cross-sectional view of FIG. 10D.

FIG. 12A is a plan view illustrating an intermediate product of the repair device that is manufactured in the first half process of the second embodiment.

FIG. 12B is a cross-sectional view taken along line A-A of FIG. 12A.

FIG. 13A is an explanatory view illustrating the manufacture of the carrier film according to the present invention, and more specifically, is a plan view illustrating the first half process of the third embodiment.

FIG. 13B is an explanatory view illustrating the manufacture of the carrier film according to the present invention, and more specifically, is a plan view illustrating the first half process of the third embodiment.

FIG. 13C is an explanatory view illustrating the manufacture of the carrier film according to the present invention, and more specifically, is a plan view illustrating the first half process of the third embodiment.

FIG. 13D is an explanatory view illustrating the manufacture of the carrier film according to the present invention, and more specifically, is a plan view illustrating the first half process of the third embodiment.

FIG. 13E is an explanatory view illustrating the manufacture of the carrier film according to the present invention, and more specifically, is a plan view illustrating the first half process of the third embodiment.

FIG. 13F is an explanatory view illustrating the manufacture of the carrier film according to the present invention, and more specifically, is a plan view illustrating the first half process of the third embodiment.

FIG. 13G is an explanatory view illustrating the manufacture of the carrier film according to the present invention, and more specifically, is a plan view illustrating the first half process of the third embodiment.

FIG. 13H is an explanatory view illustrating the manufacture of the carrier film according to the present invention, and more specifically, is a plan view illustrating the first half process of the third embodiment.

FIG. 14A is a cross-sectional view of FIG. 13A.

FIG. 14B is a cross-sectional view of FIG. 13B.

FIG. 14C is a cross-sectional view of FIG. 13C.

FIG. 14D is a cross-sectional view of FIG. 13D.

FIG. 14E is a cross-sectional view of FIG. 13E.

FIG. 14F is a cross-sectional view of FIG. 13F.

FIG. 14G is a cross-sectional view of FIG. 13G.

FIG. 14H is a cross-sectional view of FIG. 13H.

FIG. 15A is a plan view illustrating an intermediate product of the repair device that is manufactured in the first half process of the third embodiment.

FIG. 15B is a cross-sectional view taken along line A-A of FIG. 15A.

FIG. 16 is a plan view illustrating a passive matrix type full-color LED display panel that has LEDs of three colors, in which each LED is arranged in an opening that is surrounded by a light shielding wall.

FIG. 17A is a view for explaining a method for repairing the full-color LED display panel of FIG. 16, and more specifically, is a cross-sectional view illustrating the first half process.

FIG. 17B is a view for explaining the method for repairing the full-color LED display panel of FIG. 16, and more specifically, is a cross-sectional view illustrating the first half process.

FIG. 17C is a view for explaining the method for repairing the full-color LED display panel of FIG. 16, and more specifically, is a cross-sectional view illustrating the first half process.

FIG. 17D is a view for explaining the method for repairing the full-color LED display panel of FIG. 16, and more specifically, is a cross-sectional view illustrating the first half process.

FIG. 18A is a view for explaining the method for repairing the full-color LED display panel of FIG. 16, and more specifically, is a cross-sectional view illustrating the second half process.

FIG. 18B is a view for explaining the method for repairing the full-color LED display panel of FIG. 16, and more specifically, is a cross-sectional view illustrating the second half process.

FIG. 18C is a view for explaining the method for repairing the full-color LED display panel of FIG. 16, and more specifically, is a cross-sectional view illustrating the second half process.

FIG. 19 is a plan view illustrating the passive-matrix full-color LED display panel that has the LEDs and fluorescent layers of three colors, in which each LED and each fluorescent layer are placed in an opening that is surrounded by a light shielding wall, the LED emits excitation light in an ultraviolet or blue wavelength band, in such a way that the fluorescent layer is excited by the excitation light so as to emit light.

FIG. 20A is a view for explaining a method for repairing the full-color LED display panel of FIG. 19, and is a cross-sectional view illustrating the first half process.

FIG. 20B is a view for explaining the method for repairing the full-color LED display panel of FIG. 19, and is a cross-sectional view illustrating the first half process.

FIG. 20C is a view for explaining the method for repairing the full-color LED display panel of FIG. 19, and is a cross-sectional view illustrating the first half process.

FIG. 20D is a view for explaining the method for repairing the full-color LED display panel of FIG. 19, and is a cross-sectional view illustrating the first half process.

FIG. 21A is a view for explaining the method for repairing the full-color LED display panel of FIG. 19, and is a cross-sectional view illustrating the second half process.

FIG. 21B is a view for explaining the method for repairing the full-color LED display panel of FIG. 19, and is a cross-sectional view illustrating the second half process.

FIG. 21C is a view for explaining the method for repairing the full-color LED display panel of FIG. 19, and is a cross-sectional view illustrating the second half process.

FIG. 21D is a view for explaining the method for repairing the full-color LED display panel of FIG. 19, and is a cross-sectional view illustrating the second half process.

FIG. 22 is a cross-sectional view illustrating a modification of the defective pixel on the full-color LED display panel of FIG. 19.

FIG. 23A is a view for explaining a modification of the method for repairing the full-color LED display panel of FIG. 19, and more specifically, is a cross-sectional view illustrating the first half process.

FIG. 23B is a view for explaining the modification of the method for repairing the full-color LED display panel of FIG. 19, and more specifically, is a cross-sectional view illustrating the first half process.

FIG. 23C is a view for explaining the modification of the method for repairing the full-color LED display panel of FIG. 19, and more specifically, is a cross-sectional view illustrating the first half process.

FIG. 23D is a view for explaining the modification of the method for repairing the full-color LED display panel of FIG. 19, and more specifically, is a cross-sectional view illustrating the first half process.

FIG. 24A is a view for explaining the modification of the method for repairing the full-color LED display panel of FIG. 19, and more specifically, is a cross-sectional view illustrating the second half process.

FIG. 24B is a view for explaining the modification of the method for repairing the full-color LED display panel of FIG. 19, and more specifically, is a cross-sectional view illustrating the second half process.

FIG. 24C is a view for explaining the modification of the method for repairing the full-color LED display panel of FIG. 19, and more specifically, is a cross-sectional view illustrating the second half process.

FIG. 25 is a front view illustrating an embodiment of the repair apparatus for repairing the LED display panel according to the present invention.

### MODE FOR CARRYING OUT THE INVENTION

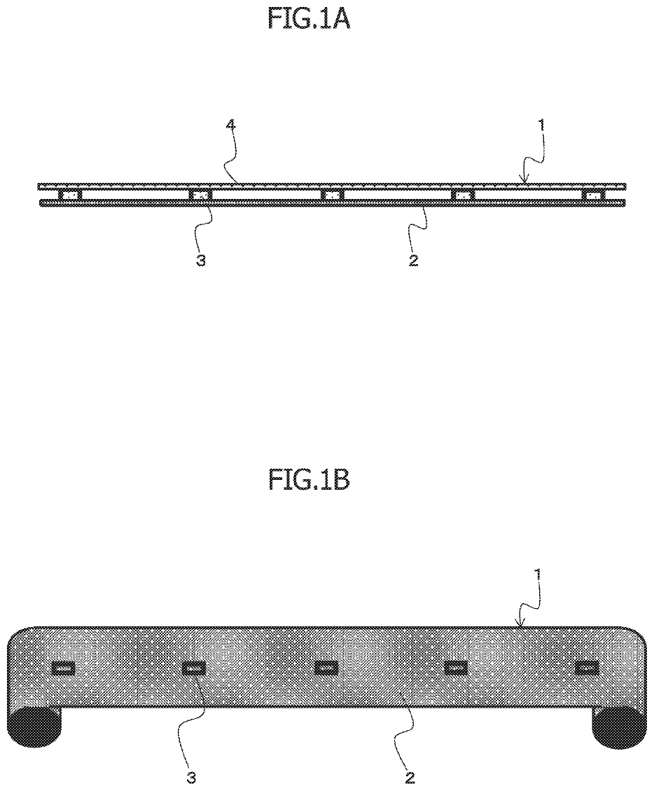

Hereinafter, embodiments of the present invention will be described in detail with reference to the accompanying drawings. FIG. 1A is a center line cross-sectional view illustrating an embodiment of the carrier film according to the present invention, and FIG. 1B is its perspective view. The carrier film 1 is for repairing defective pixels on the full-color LED display panel, and includes a support film 2, a plurality of repair devices 3, and a protective film 4.

The support film 2 adhesively supports one end surface of each repair device 3, which will be described later, and is the resin film or ultraviolet transmissive film such as the quartz film on the surface of which the gluing agent has been applied. The support film 2 may either be a tape that has a long axis in one direction or a two-dimensional sheet. In the following descriptions, the support film 2 will be shown as the tape.

Furthermore, on the surface of the support film 2 on which the repair devices 3 are arranged, the resin may be applied by using, for example, the micro dispenser, along both edges of the support film 2 that are parallel to the arrangement direction of the repair devices 3. The resin may be applied such that the convex portions that are taller than the repair devices 3 are formed continuously or intermittently. This can prevent the repair devices 3 from rubbing against the support film 2 and dropping off when the carrier film 1 is wound up on the roll or pulled out from the wound roll.

The plurality of repair devices 3 are provided on one surface of the tape-shaped support film 2 and are arranged side-by-side in the longitudinal direction. Each repair device 3 is provided with the repair element for repairing the defective pixel 21 on the full-color LED display panel, and the repair element is provided in the opening 7 that is surrounded by the light shielding wall 6.

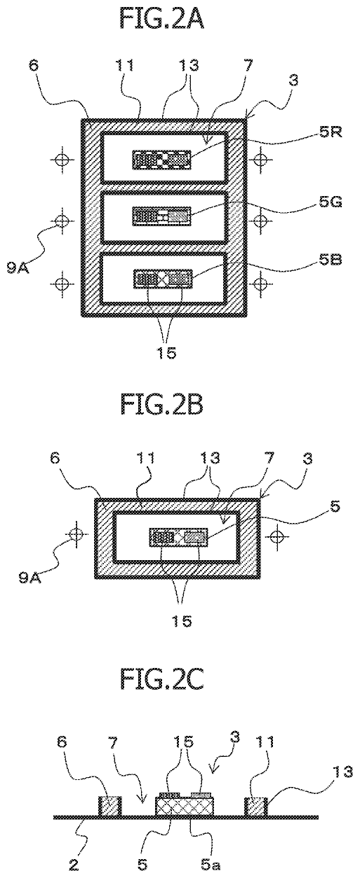

Specifically, if the full-color LED display panel has micro-LED chips (hereinafter, simply referred to as “LEDs”) 5 of the three colors red, green, and blue that are arranged in a matrix form, each repair device 3 has the pixel element for repair in which LEDs 5R, 5G, and 5B for respective colors which serve as the repair elements are respectively arranged in three openings 7 that are surrounded by the light shielding wall 6 as illustrated in FIG. 2A. Alternatively, each repair device 3 has a subpixel element for repair in which one LED 5 of corresponding color is arranged in one opening 7 that is surrounded by the light shielding wall 6 as illustrated in FIG. 2B. The light emitting surface 5a of each LED 5 is adhered to the support film 2, as illustrated in FIG. 2C. The three openings 7 in the light shielding wall 6 are formed side-by-side at the same array pitch as those of the LEDs 5R, 5G, and 5B in the full-color LED display panel. The same will be applicable hereinafter.

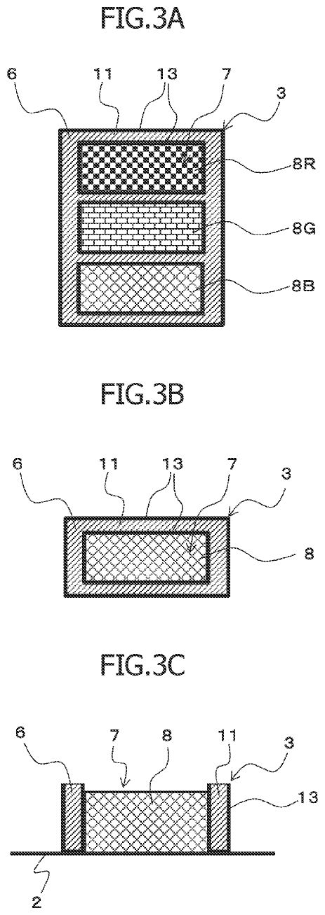

Alternatively, if the LEDs 5 of the full-color LED display panel emit excitation light in the ultraviolet or blue wavelength band, the repair device 3 has the pixel element for repair in which the fluorescent layers 8R, 8G, and 8B for respective colors are respectively arranged in the three openings 7 that are surrounded by the light shielding wall 6 as illustrated in FIG. 3A, the fluorescent layers 8R, 8G, and 8B serve as the repair elements, in such a way that the fluorescent layers 8R, 8G, and 8B are excited by the excitation light so as to emit light. Alternatively, each repair device has the subpixel element for repair in which one fluorescent layer 8 of corresponding color is arranged in one opening 7 that is surrounded by the light shielding wall 6 as illustrated in FIG. 3B. The end surface on one side of the fluorescent layer 8 is adhered to the support film 2 as illustrated in FIG. 3C.

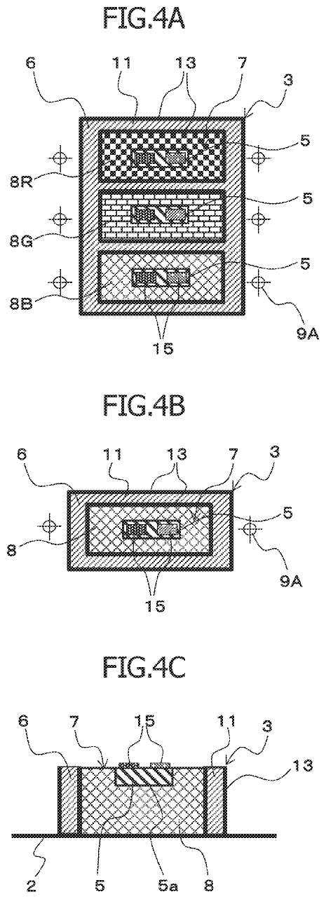

Alternatively, if the LEDs 5 of the full-color LED display panel emit excitation light in the ultraviolet or blue wavelength band, the repair device 3 has the pixel element for repair that has the LEDs 5 and fluorescent layers 8R, 8G, and 8B for respective colors in the three openings 7 that are surrounded by the light shielding wall 6 as illustrated in FIG. 4A, the LEDs 5 and fluorescent layers 8R, 8G, and 8B serve as the repair elements, in such a way that the fluorescent layers on the light emitting surface 5a of the LEDs are excited by the excitation light so as to emit light. Alternatively, each repair device has the subpixel element for repair in which one LED 5 and one fluorescent layer 8 of corresponding color are arranged in one opening 7 that is surrounded by the light shielding wall 6 as illustrated in FIG. 4B. The end surface of the fluorescent layer 8 opposite from the LED 5 is adhered to the support film 2 as illustrated in FIG. 4C.

FIGS. 2A and 2B and FIGS. 4A and 4B illustrate the repair alignment marks 9A that are provided on the support film 2. The repair alignment marks 9A are provided to correspond to the repair alignment marks 9B that are provided on the wiring board 17, which will be described later. The repair alignment marks 9A are spaced by a predetermined distance from one another on the center line connecting the two electrodes 15 of the LED 5.

The protective film 4 is provided opposite to the support film 2 across the repair devices 3. The protective film 4 for protecting the repair devices 3 is adhered to the repair devices 3 in manner such that it can be easily peeled off with the gluing agent that is applied to the surface of the protective film 4. In this case, it is preferable to select the gluing agent of the protective film 4 that has less adhesive force than that of the support film 2. The protective film 4 is peeled off from the repair devices 3 prior to repairing the defective pixel 21 on the full-color LED display panel.

Next, the manufacture of the carrier film 1 will be described.

The first embodiment will now be described. Each repair device 3 has a pixel element for repair in which the LEDs 5R, 5G and 5B for respective colors are respectively arranged in the three openings 7 that are surrounded by the light shielding wall 6 as illustrated in FIG. 2A.

### First Embodiment

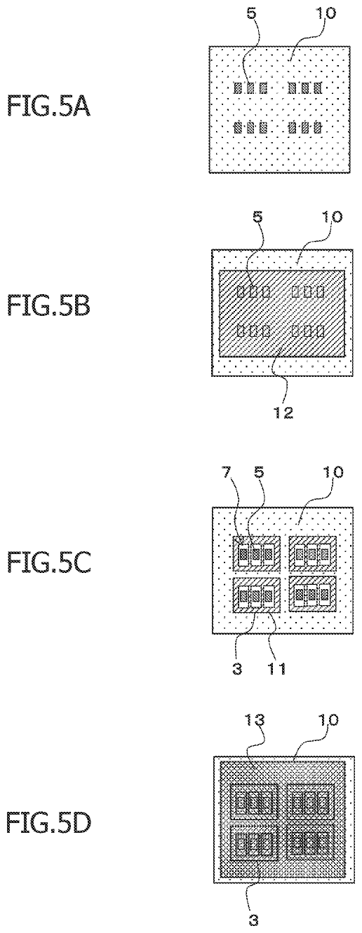

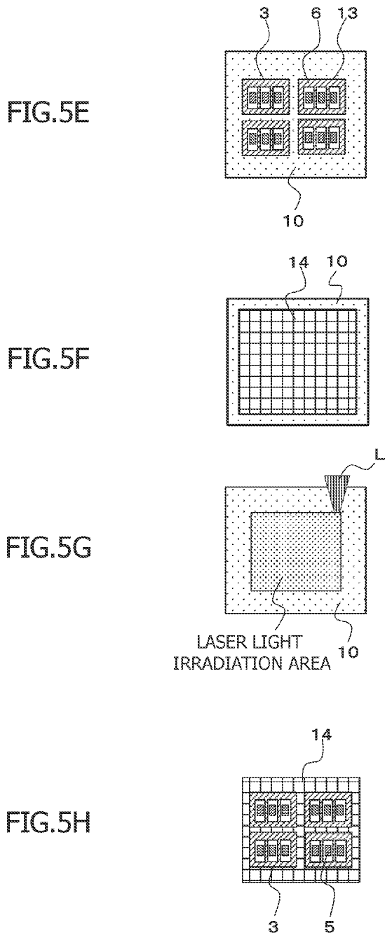

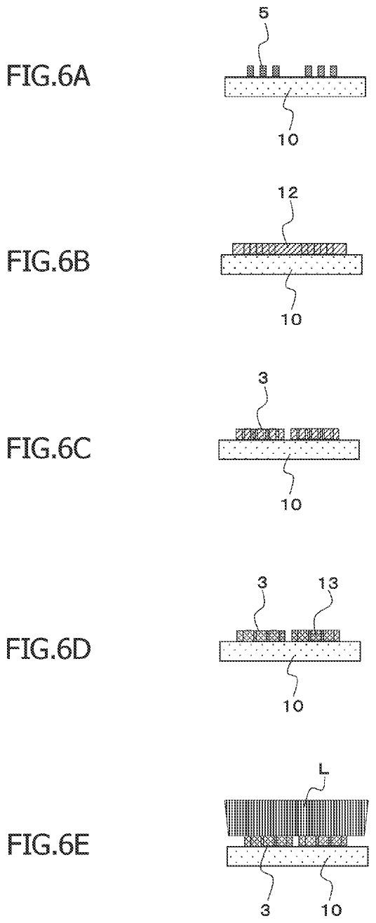

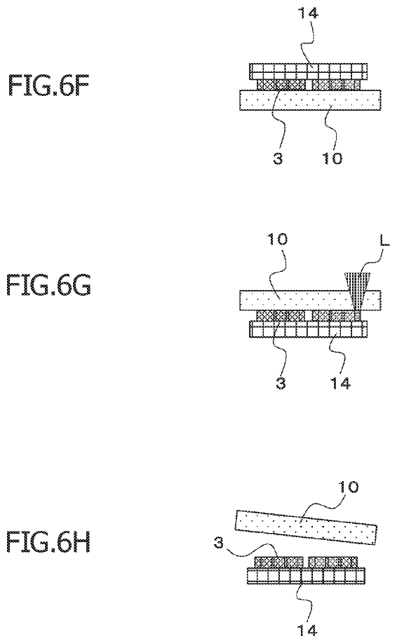

As illustrated in FIGS. 5A and 6A, the LEDs 5R, 5G and 5B of three colors are arranged side by side at a predetermined arrangement pitch, and the light emitting surface 5a of each LED is adhered onto the transparent substrate 10. As illustrated in FIGS. 5B and 6B, for example, the transparent photosensitive resin 12 for forming the partition wall 11 which is the base material of the light shielding wall 6 is uniformly applied to cover the LEDs 5R, 5G and 5B. The coating thickness of the photosensitive resin 12 is substantially equal to the thickness of the LEDs 5.

Next, as illustrated in FIGS. 5C and 6C, the exposure and development are performed by the photolithography technique by using the photomask (not illustrated) to form the outer shape of each repair device 3, and the three openings 7 surrounded by the partition wall 11 that is made of the transparent resin are formed such that the LEDs 5R, 5G, and 5B respectively exist in the openings 7.

Furthermore, as illustrated in FIGS. 5D and 6D, the thin film 13 is provided to form the light shielding wall 6 by sputtering, vapor deposition, or electroless plating. The thin film 13 is a film of metal such as aluminum, aluminum alloy, or nickel, and covers the transparent substrate 10 and repair devices 3 to reflect or absorb the light that is emitted from the LEDs 5 (the step of forming the thin film).

Furthermore, as illustrated in FIGS. 5E and 6E, the laser beam L, for example, in the visible region or the ultraviolet region, is irradiated from the repair device 3 side to remove the thin film 13 that has been deposited on the top surface of the light shielding wall 6, the bottom surface of the openings 7 that include the LEDs 5 which are surrounded by the light shielding wall 6, and the surface of the transparent substrate 10 that is outside the light shielding wall 6 (the step of removing the unnecessary thin film).

The light shielding wall 6 may be a black matrix. In this case, the step of forming the thin film and the step of removing the unnecessary thin film can be omitted. Furthermore, if each repair device 3 has a sub-pixel element for repair in which one LED 5 of corresponding color is arranged in one opening 7 that is surrounded by the light shielding wall 6, the transparent substrate 10 may be a sapphire substrate. That is, the photosensitive resin 12 may be applied over the LED 5 that is formed on the sapphire substrate, exposed, and developed to form the light shielding wall 6 in the same manner as described above.

Next, the adhesive is applied to the end surface opposite from the transparent substrate 10 of the light shielding wall 6 by using, the micro dispenser, for example. Then, the transparent first dummy substrate 14 is adhered as illustrated in FIGS. 5F and 6F. The first dummy substrate 14 is, for example, made of quartz glass and transmissive to UV light.

Subsequently, as illustrated in FIGS. 5G and 6G, the laser beam L is irradiated from the transparent substrate 10 side using, for example, the 266-nm picosecond laser to perform laser lift-off of the repair devices 3 from the transparent substrate 10.

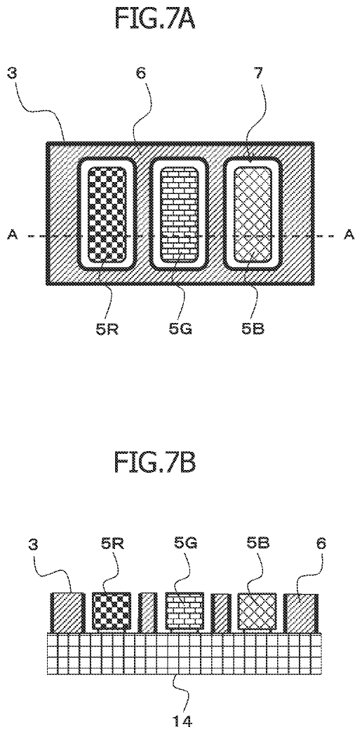

Then, when the transparent substrate 10 is peeled off as illustrated in FIGS. 5H and 6H, the plurality of repair devices 3 are transferred to and remain on the first dummy substrate 14 as illustrated in FIGS. 7A and 7B, in which each repair device has the LEDs 5R, 5G and 5B for respective colors, and each LED is arranged in the openings 7 that are surrounded by the light shielding wall 6.

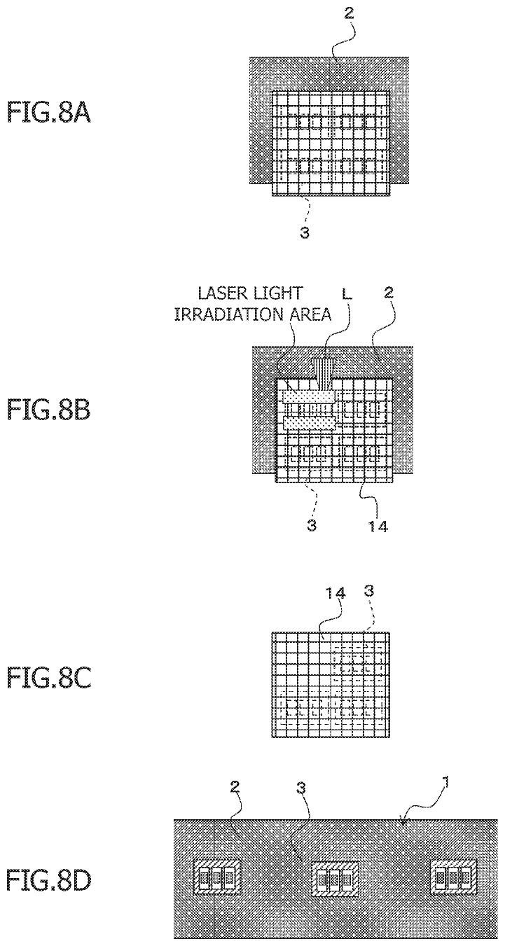

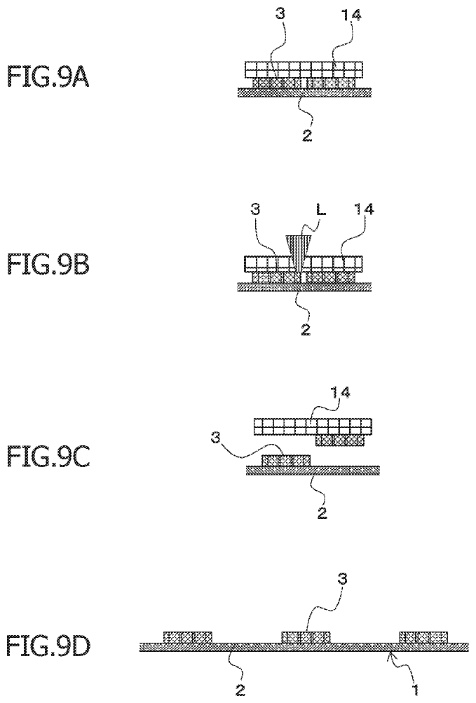

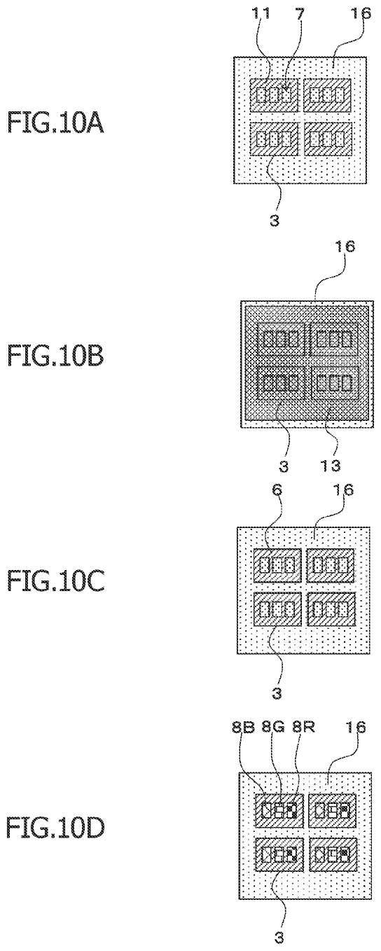

Next, as illustrated in FIGS. 8A and 9A, the selected one of the repair devices 3 is positioned on the longitudinal central axis of the tape-shaped support film 2. Also, the first dummy substrate 14 and support film 2 are relatively positioned such that the pair of repair alignment marks 9A provided in advance on the support film 2 matches the line that connects the two electrodes 15 of the LED 5 across the LED 5 of the repair device 3. The first dummy substrate 14 and support film 2 are then pressed against each other to adhere the selected repair device 3 to the support film 2.

The repair alignment marks 9A of the support film 2 may be formed by laser processing on the line that connects the two electrodes 15 of the LED 5 of the repair device 3 after the repair device 3 is adhered to the support film 2.

Next, as illustrated in FIGS. 8B and 9B, the laser beam L is irradiated from the first dummy substrate 14 side to the selected repair device 3 by using, for example, the 266-nm picosecond laser to perform laser lift-off of the selected repair device 3 from the first dummy substrate 14.

Then, as illustrated in FIGS. 8C and 9C, when the first dummy substrate 14 is peeled off, the selected repair device 3 is transferred to and remains on the support film 2. On the other hand, the remaining repair devices 3 that are not selected remain on the first dummy substrate 14 side without being transferred to the support film 2 due to the difference in the adhesive force between the repair devices 3 and the first dummy substrate 14, and between the repair devices 3 and the support film 2. Note that the two repair devices 3 of the first dummy substrate 14 on the near side in FIG. 9C are not illustrated.

Thereafter, the steps of FIGS. 8A to 8C and FIGS. 9A to 9C are repetitively performed. As a result, as illustrated in FIGS. 8D and 9D, the plurality of repair devices 3 are transferred in a side-by-side arrangement at a predetermined interval along the longitudinal central axis of the support film 2 to bring the tape-shaped carrier film 1 to completion.

Next, the second embodiment will be described. Each repair device 3 has the fluorescent layers 8R, 8G, and 8B for respective colors, and each fluorescent layer is arranged in the three openings 7 that are surrounded by the light shielding wall 6 as illustrated in FIG. 3A.

### Second Embodiment

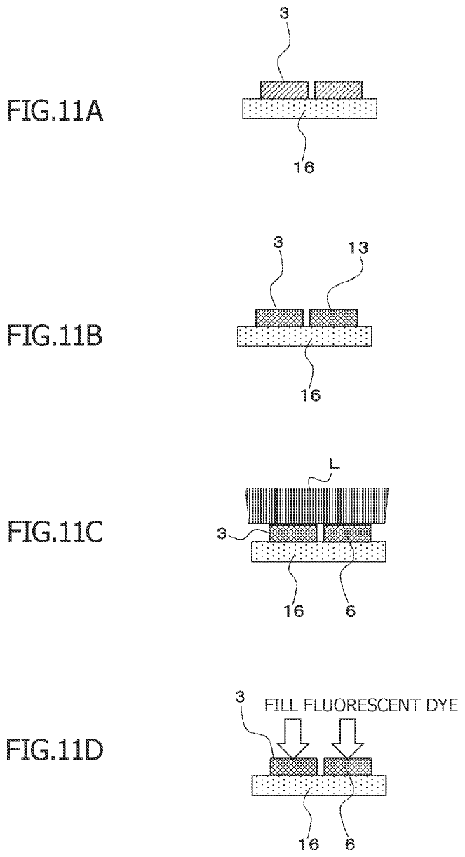

First, as illustrated in FIGS. 10A and 11A, the partition wall 11 which is the base material of the light shielding wall 6 is formed on the second dummy substrate 16 that is made of quartz in the same manner as in FIGS. 5B and 5C. Specifically, first, the transparent photosensitive resin 12 is uniformly applied onto the second dummy substrate 16. In this case, the photosensitive resin 12 may preferably be thicker than the height of the LEDs 5 from the substrate surfaces to the top surfaces which are arranged on the full-color LED display panel.

Specifically, the transparent photosensitive resin 12 is applied with such thickness that the height of the partition wall 11 formed by the exposure and development using the photomask becomes higher than the height from the upper surface of the full-color LED display panel to the top surfaces of the LEDs 5 by about 10 to 40 μm. The photosensitive resin 12 used here is a high-aspect material capable of having a height-to-width aspect ratio of approximately three or more, and is preferably, for example, SU-8 3000 manufactured by Nippon Kayaku Co., Ltd., or a permanent film photoresist for Micro Electronic Mechanical System (MEMS) such as TMMR 52000 series manufactured by Tokyo Ohka Kogyo Co., Ltd. As a result, a sufficient amount of fluorochrome to be filled in the openings 7 that are surrounded by the partition wall 11 (or the light shielding wall 6) can be secured, and the wavelength conversion efficiency of the fluorescent layer 8 can be improved. Therefore, a high-luminance display screen can be realized.

Next, the exposure and development are performed by the photolithography technique using the photomask (not illustrated) to form the outer shape of each repair device 3, and the three openings 7 surrounded by the partition wall 11 that is made of the transparent resin are formed. In this case, the arrangement pitch of the three openings 7 is the same as that of the LEDs 5R, 5G, and 5B of the full-color LED display panel as described above.

Then, as illustrated in FIGS. 10B and 11B, the thin film 13 is provided to form the light shielding wall 6 by sputtering, vapor deposition, or electroless plating. The thin film 13 is a film of metal such as aluminum, aluminum alloy, or nickel, and covers the second dummy substrate 16 and partition wall 11 to reflect or absorb the excitation light that is emitted from the LEDs 5 and the fluorescence of the fluorescent layer 8 that is excited by the excitation light so as to emit light.

Subsequently, as illustrated in FIGS. 10C and 11C, the laser beam L, for example, in the visible region or the ultraviolet region, is irradiated from the light shielding wall 6 side to remove the thin film 13 that has been deposited on the top surface of the light shielding wall 6, the bottom surfaces of the openings 7 which are surrounded by the light shielding wall 6, and the surface of the second dummy substrate 16 that is outside the light shielding wall 6.

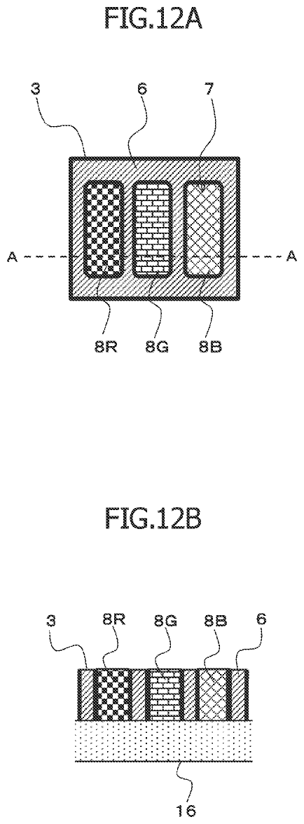

Next, as illustrated in FIGS. 10D and 11D, the fluorescent resists that contain red, green, and blue fluorochrome (pigment or dye) are respectively filled in the three openings 7 that are surrounded by the light shielding wall 6, for example, by inkjet, and are dried to form the fluorescent layers 8R, 8G and 8B. Alternatively, after applying the fluorescent resists onto the entire surface of the second dummy substrate 16, the exposure and development steps using the photomask may be performed on the fluorescent resists for respective colors to form the fluorescent layers 8R, 8G, 8B for respective colors in the three openings 7 that are surrounded by the light shielding wall 6. As a result, as illustrated in FIGS. 12A and 12B, each repair device 3 is complete, in which the fluorescent layers 8R, 8G, and 8B for respective colors are provided in the openings 7 that are surrounded by the light shielding wall 6. The fluorescent resist is not particularly limited, but may preferably be a mixture of fluorochrome that has large and small particle sizes.

Thereafter, each repair device 3 is transferred to the support film 2 through the same steps as in the first embodiment, and as illustrated in FIG. 1B, the plurality of repair devices 3 are arranged side-by-side at a predetermined interval along the longitudinal central axis of the support film 2 to bring the tape-shaped carrier film 1 to completion.

Next, the third embodiment will be described. Each repair device 3 has the pixel element for repair, in which each LED 5 and fluorescent layer 8 for each color are arranged in the three openings 7 that are surrounded by the light shielding wall 6 as illustrated in FIG. 4A, the LEDs 5 and fluorescent layer 8 serve as the repair elements, in such a way that the fluorescent layers 8 on the light emitting surface 5a of the LEDs 5 are excited by the excitation light that is emitted from the LEDs 5 so as to emit light.

### Third Embodiment

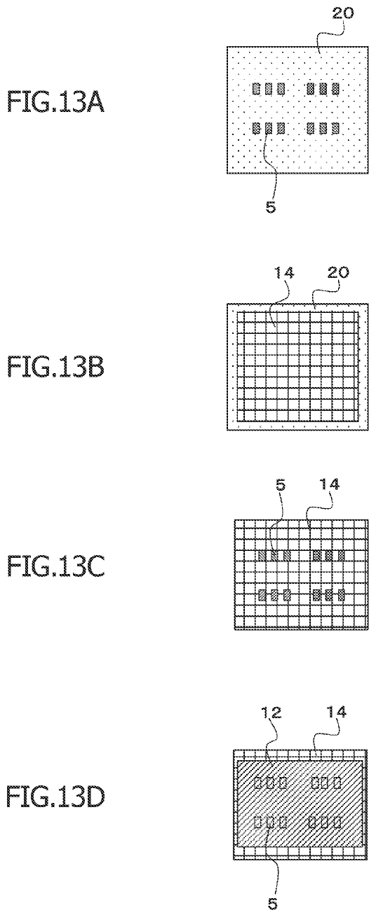

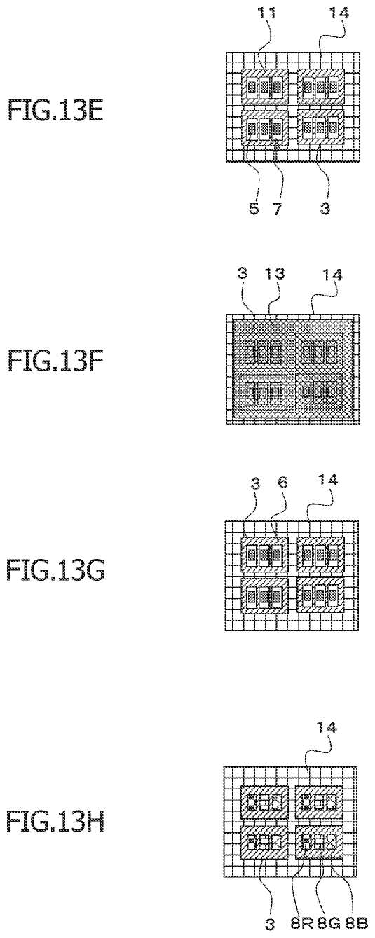

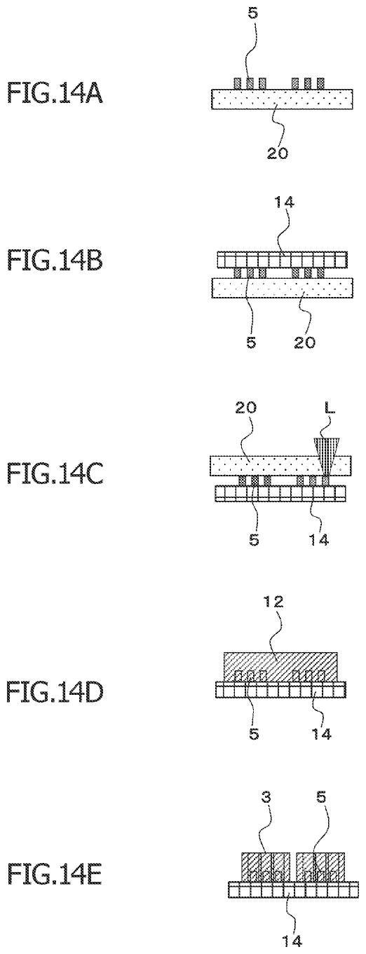

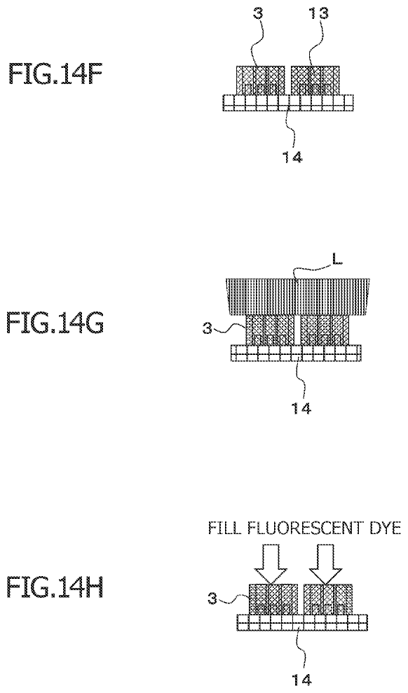

First, as illustrated in FIGS. 13A and 14A, the plurality of LEDs 5 for emitting the excitation light in the ultraviolet or blue wavelength band are formed on the sapphire substrate 20, and the transparent first dummy substrate 14 made of quartz glass, for example, is installed to cover the LEDs 5 as illustrated in FIGS. 13B and 14B. The first dummy substrate 14 is adhered to the electrode 15 side of the LEDs 5 by means of the gluing agent or adhesive applied to the surface of the first dummy substrate 14. Then, as illustrated in FIG. 14C, the laser beam L is irradiated from the sapphire substrate 20 side using, for example, the 266-nm picosecond laser to perform laser lift-off of the plurality of LEDs 5 from the sapphire substrate 20. As a result, as illustrated in FIG. 13C, the plurality of LEDs 5 is transferred to the first dummy substrate 14.

Next, as illustrated in FIGS. 13D and 14D, the transparent photosensitive resin 12 is uniformly applied onto the first dummy substrate 14. In this case, the photosensitive resin 12 may preferably be thicker than the height of the top surfaces of LEDs 5 from the surface of the first dummy substrate 14.

Specifically, regarding the thickness of the transparent photosensitive resin 12, the transparent photosensitive resin 12 is applied such that the partition wall 11 formed by the exposure and development using the photomask becomes higher than the height from the surface of the first dummy substrate 14 to the top surfaces of the LEDs 5 by about 10 to 40 μm. The photosensitive resin 12 used here is a high-aspect material capable of having a height-to-width aspect ratio of approximately three or more, and is preferably, for example, SU-8 3000 manufactured by Nippon Kayaku Co., Ltd., or a permanent film photoresist for Micro Electronic Mechanical System (MEMS) such as TMMR 52000 series manufactured by Tokyo Ohka Kogyo Co., Ltd. As a result, a sufficient amount of fluorochrome to be filled in the openings 7 that are surrounded by the partition wall 11 (or the light shielding wall 6) can be secured, and the wavelength conversion efficiency of the fluorescent layer 8 can be improved. Therefore, a high-luminance display screen can be realized.

Next, as illustrated in FIGS. 13E and 14E, the exposure and development are performed by the photolithography technique by using the photomask (not illustrated) to form the outer shape of each repair device 3, and the three openings 7 surrounded by the partition wall 11 that is made of the transparent resin are formed such that the LEDs 5 exist in the openings 7.

Then, as illustrated in FIGS. 13F and 14F, the thin film 13 is provided to form the light shielding wall 6 by sputtering, vapor deposition, or electroless plating. The thin film 13 is a film of metal such as aluminum, aluminum alloy, or nickel, and covers the first dummy substrate 14 and partition wall 11 to reflect or absorb the excitation light that is emitted from the LED 5 and the fluorescence of the fluorescent layer 8 that is excited by the excitation light so as to emit light.

Subsequently, as illustrated in FIGS. 13G and 14G, the laser beam L, for example, in the visible region or the ultraviolet region, is irradiated from the light shielding wall 6 side to remove the thin film 13 that has been deposited on the top surface of the light shielding wall 6, the bottom surfaces of the openings 7 which include the LEDs 5 that are surrounded by the light shielding wall 6, and the surface of the first dummy substrate 14 that is outside the light shielding wall 6.

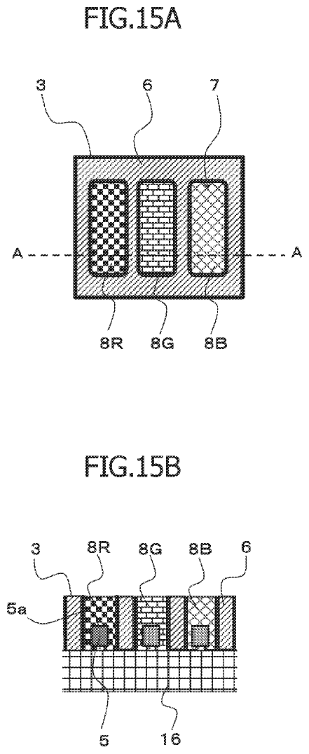

Next, as illustrated in FIGS. 13H and 14H, the fluorescent resists that contain red, green, and blue fluorochrome (pigment or dye) are respectively filled in the three openings 7 that are surrounded by the light shielding wall 6, for example, by inkjet, and are dried to form the fluorescent layers 8. Alternatively, after applying the fluorescent resists onto the entire surface of the first dummy substrate 14, the exposure and development steps using the photomask may be performed on the fluorescent resists for respective colors to form the fluorescent layers 8R, 8G, 8B for respective colors in the three opening 7 that are surrounded by the light shielding wall 6. As a result, as illustrated in FIGS. 15A and 15B, each repair device 3 is complete, in which the LEDs 5 and the fluorescent layers 8R, 8G, 8B for respective colors are arranged in the openings 7 that are surrounded by the light shielding wall 6.

Thereafter, each repair device 3 is transferred to the support film 2 through the same steps as in the first embodiment, and as illustrated in FIG. 1B, the plurality of repair devices 3 are arranged side by side at a predetermined interval along the longitudinal central axis of the support film 2 to bring the tape-shaped carrier film 1 to completion.

Although the repair devices 3 have the pixel elements for repair in this embodiment, the repair devices 3 may also have the subpixel elements for repair. Even in such case, the carrier film 1 can be manufactured by carrying out the same steps as described above.

Next, the method for repairing the LED display panel by using the carrier film 1 according to the present invention will be described.

First, the method for repairing the LED display panel by using the carrier film 1 that is manufactured according to the first embodiment will be described.

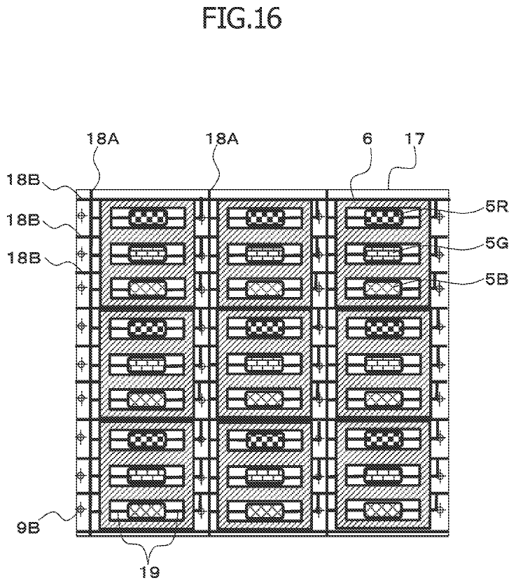

FIG. 16 is the plan view illustrating the passive matrix type full-color LED display panel in which the LEDs 5 of three colors are arranged. As illustrated in FIG. 16, the LEDs 5R, 5G and 5B of three colors are arranged at the intersections of the vertical and horizontal wirings 18A, 18B on the wiring board 17, and the light shielding wall 6 is provided to surround the LEDs 5R, 5G and 5B for respective colors. Furthermore, the repair alignment marks 9B corresponding to the repair alignment marks 9A of the carrier film 1 are provided at the opposite ends of the wiring board 17, and specifically, are provided across the respective LEDs 5R, 5G, and 5B and in the leading direction of the lead wirings 19 that are electrically connected to the electrodes 15 of the LEDs 5.

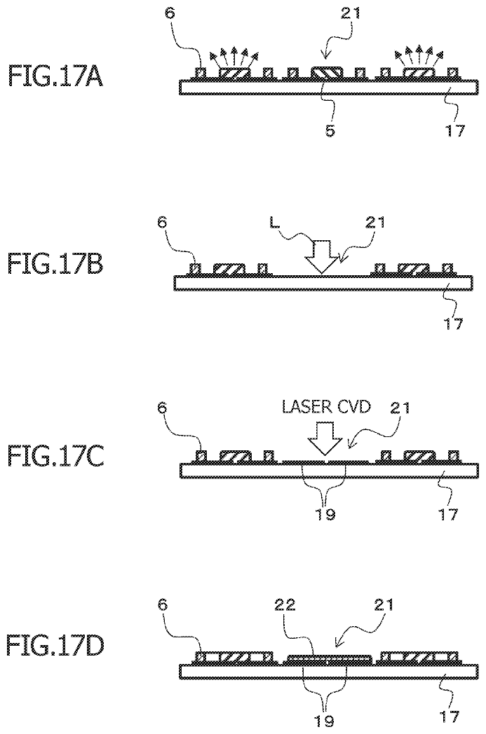

First, as illustrated in FIG. 17A, the wiring board 17 is energized for lighting inspection. Then, an LED 5 that is not on or has a brightness level that is not a permissible value, or an LED 5 that has an emission wavelength that is not a permissible value, is detected, and the position coordinates (or address) of the defective pixel 21 that includes such LED 5 (defective element) are stored.

Next, as illustrated in FIG. 17B, the irradiation position of the laser beam L is determined based on the stored position coordinates (or address) of the defective pixel 21, and the laser beam L is irradiated on the defective pixel 21 to perform laser cutting. As a result, the LED 5 and light shielding wall 6 of the defective pixel 21 are removed.

Next, as illustrated in FIG. 17C, the lead wiring 19 corresponding to the defective pixel 21 on the wiring board 17 is repaired by forming, for example, the tungsten auxiliary wiring (lead wiring 19) using the known laser CVD technique.

Subsequently, as illustrated in FIG. 17D, the adhesive 22 is applied to the defective pixel 21 by inkjet, for example, excluding the lead wiring 19 inside the defective pixel 21. In this case, the adhesive 22 to be used may be a heat-curing adhesive or an ultraviolet curing-type adhesive, and may be appropriately selected and used depending on the situation.

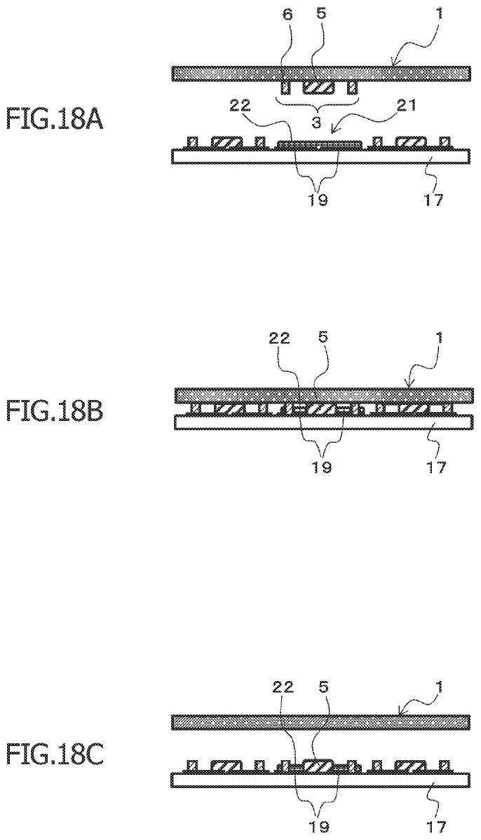

Next, as illustrated in FIG. 18A, one repair device 3 of the carrier film 1 is positioned on the defective pixel 21. In this case, the repair alignment marks 9A are provided on the transparent support film 2 of the carrier film 1 to correspond to the repair device 3 and the repair alignment marks 9B are provided to correspond to the defective pixel 21 on the wiring board 17 that is observed through the transmissive support film 2, and the repair alignment marks 9A and 9B are aligned to match each other or have a predetermined positional relationship.

Next, as illustrated in FIG. 18B, the repair device 3 is pressed against the wiring board 17 from the carrier film 1 side. As a result, the electrodes 15 of the LED 5 electrically contact the lead wiring 19 in the defective pixel 21. Then, the wiring board 17 is energized in this state, and the lighting of the repair device 3 is inspected.

When the LED 5 is determined to be non-defective as a result of the lighting inspection, the adhesive 22 is heat-cured or UV-cured, and the repair device 3 is adhesively fixed to the defective pixel 21 while maintaining the electrical connection state between the electrodes 15 of the LED and the lead wiring 19.

Then, as illustrated in FIG. 18C, when the carrier film 1 is torn off from the wiring board 17, the carrier film 1 is peeled off from the device 3 due to the difference in strength between the viscosity of the support film 2 of the carrier film 1 and the adhesive force of the adhesive, and the repair device 3 remains on the wiring board 17 to complete the repairing of the defective pixel 21.

Next, the method for repairing the LED display panel by using the carrier film 1 that is manufactured according to the second embodiment will be described.

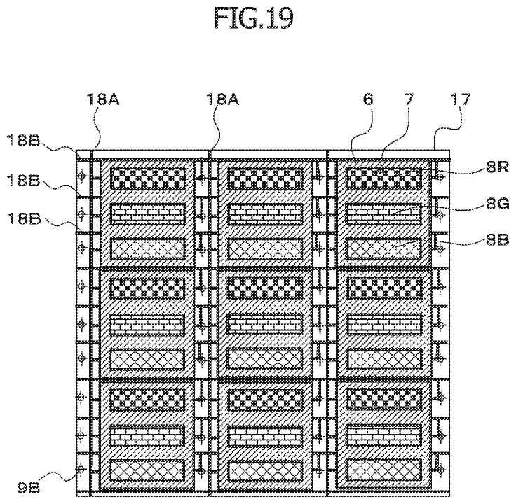

FIG. 19 is a plan view illustrating the passive-matrix full-color LED display panel that has pixels arranged, each pixel has the LEDs 5 and fluorescent layers 8 of three colors in the openings 7 that are surrounded by the light shielding wall 6, the LEDs 5 emit excitation light in the ultraviolet or blue wavelength band, in such a way that the fluorescent layers 8 of three colors at the light emitting surface 5a of the LEDs 5 are excited by the excitation light so as to emit light.

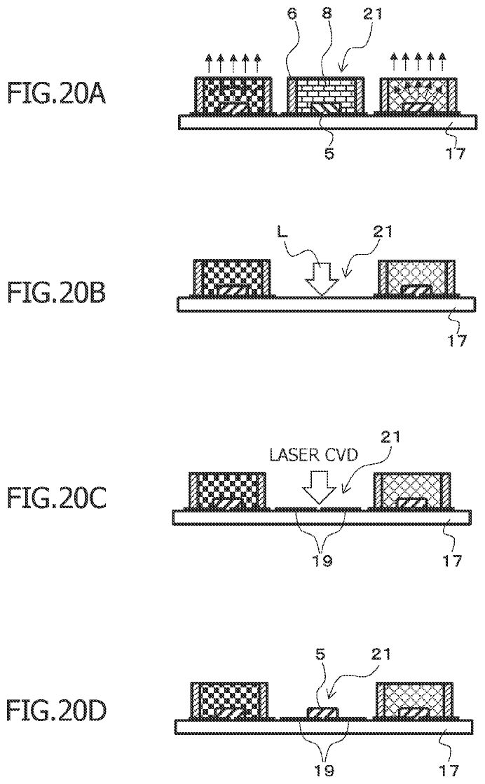

First, as illustrated in FIG. 20A, the wiring board 17 is energized for lighting inspection. Then, an LED 5 that is not on or has a brightness level is not a permissible value, or an LED 5 that has an emission wavelength that is not a permissible value is detected, and the position coordinates (or address) of the defective pixel 21 that includes such LED 5 (defective element) are stored.

Next, as illustrated in FIG. 20B, the irradiation position of the laser beam L is determined based on the stored position coordinates (or address) of the defective pixel 21, and the laser beam L is irradiated on the defective pixel 21 to perform laser cutting. As a result, the LED 5, fluorescent layer 8 and light shielding wall 6 of the defective pixel 21 are removed.

Then, as illustrated in FIG. 20C, the lead wiring 19 corresponding to the defective pixel 21 on the wiring board 17 is repaired by forming, for example, the tungsten auxiliary wiring using the known laser CVD technique.

Subsequently, the electrode 15 side becomes the adhesive sheet side, one LED 5 is selected from the plurality of LEDs 5 that are transferred from the sapphire substrate 20 to the adhesive sheet by the laser lift-off, and the light emitting surface 5a of the LED 5 is attached to the tip of the carrying tool (not illustrated) and carried from the adhesive sheet onto the wiring board 17. Then, as illustrated in FIG. 20D, the selected LED 5 is positioned on the defective pixel 21, and the electrodes 15 and the repaired lead wiring 19 are in electrical contact with each other. In this state, the prober is used for lighting inspection of the LED 5 to determine the quality of the selected LED 5. Alternatively, the wiring board 17 may be energized for lighting inspection of the LED 5.

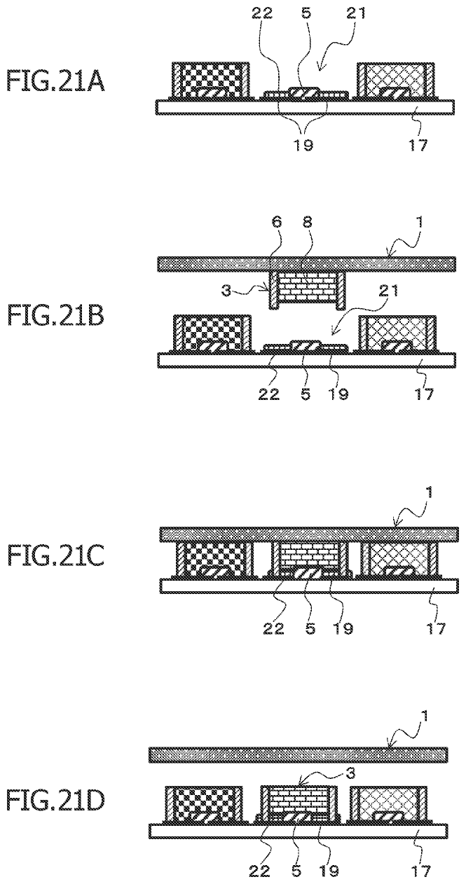

Next, when the selected LED 5 is determined to be non-defective, while maintaining the electrical connection state between the electrodes 15 of LED 5 and the lead wiring 19 of defective pixel 21, the micro dispenser, for example, is used to apply the adhesive 22 around the LED 5 in the defective pixel 21 as illustrated in FIG. 21A. As described, the adhesive 22 used may be a heat-curing adhesive or an ultraviolet curing-type adhesive, and may be appropriately selected and used depending on the situation.

Subsequently, as illustrated in FIG. 21B, one repair device 3 of the carrier film 1 is positioned on the defective pixel 21. In this case, the positioning between the repair device 3 and the defective pixel 21 does not require high accuracy as compared to the repair performed using the repair device 3 of the first embodiment. Thus, the alignment may be performed by observing the surface of the wiring board 17 through the transmissive carrier film 1 and positioning one repair device 3 of the carrier film 1 on the defective pixel 21.

Next, as illustrated in FIG. 21C, the repair device 3 is pressed against the wiring board 17 from the carrier film 1 side. As a result, the top of the light shielding wall 6 of the repair device 3 comes into contact with the adhesive 22. Furthermore, the adhesive 22 is heat-cured or UV-cured to adhesively fix the repair device 3 to the defective pixel 21.

Then, as illustrated in FIG. 21D, when the carrier film 1 is torn off from the wiring board 17, the carrier film 1 is peeled off from the device 3 due to the difference in strength between the viscosity of the support film 2 of the carrier film 1 and the adhesive force of the adhesive 22, and the repair device 3 remains on the wiring board 17 to complete the repairing of the defective pixel 21.

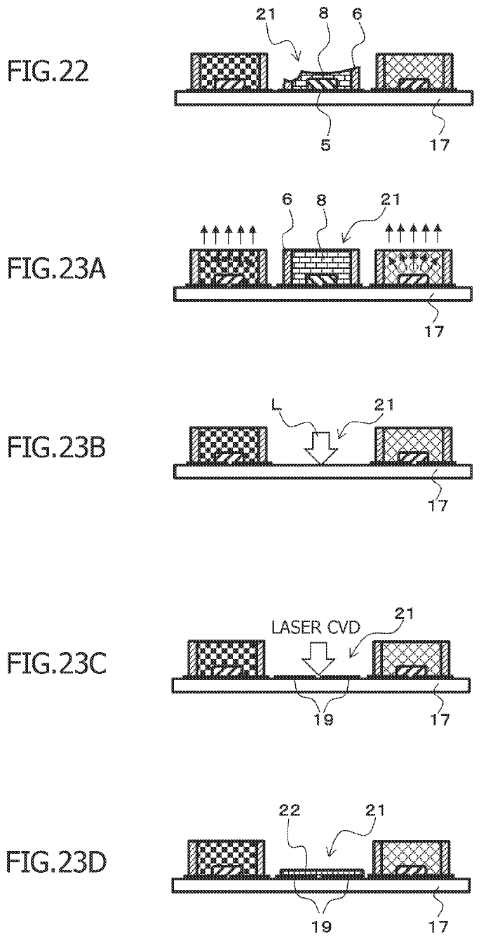

The method for repairing a defective pixel 21 that has been determined to be defective as a result of the lighting inspection of the full-color LED display panel has been described. However, the present invention is not limited to these embodiments, and the repair can also be performed on defective pixels 21 to which any appearance defect is detected on at least one of the light shielding wall 6 and fluorescent layer 8 as illustrated in FIG. 22 as a result of appearance inspection to the pixels on the full-color LED display panel. In this case, if the LED 5 is determined as non-defective as a result of the lighting inspection, the processes as illustrated in FIGS. 21A to 21D may be performed after the light shielding wall 6 and the fluorescent layer 8 (defective element) of the defective pixel 21 are removed by laser ablation.

Next, the method for repairing the LED display panel by using the carrier film 1 that is manufactured according to the third embodiment will be described.

Such repair method can be applied to the passive-matrix full-color LED display panel that has pixels arranged as illustrated in FIG. 19, and each of which has the LEDs 5 and fluorescent layers 8R, 8G and 8B of three colors arranged in the openings 7 that are surrounded by the light shielding wall 6, the LEDs 5 emit excitation light in the ultraviolet or blue wavelength band, in such a way that the fluorescent layers 8R, 8G and 8B of three colors on the light emitting surface 5a of the LEDs 5 are excited by the excitation light so as to emit light.

First, as illustrated in FIG. 23A, the wiring board 17 is energized for lighting inspection. Then, an LED 5 that is not on or has a brightness level that is not a permissible value, or an LED 5 that has an emission wavelength that is not a permissible value is detected, and the position coordinates (or address) of the defective pixel 21 that includes such an LED 5 (defective element) are stored.

Next, as illustrated in FIG. 23B, the irradiation position of the laser beam L is determined based on the stored position coordinates (or address) of the defective pixel 21, and the laser beam L is irradiated on the defective pixel 21 to perform laser cutting. As a result, the LEDs 5 of three colors, fluorescent layer 8 and light shielding wall 6 of the defective pixel 21 are removed.

Next, as illustrated in FIG. 23C, the lead wiring 19 corresponding to the defective pixel 21 on the wiring board 17 is repaired by forming, for example, the tungsten auxiliary wiring (lead wiring 19) using a known laser CVD technique.

Subsequently, as illustrated in FIG. 23D, the adhesive 22 is applied to the defective pixel 21 by inkjet, for example, excluding the lead wiring 19 inside the defective pixel 21. In this case, the adhesive 22 to be used may be a heat-curing adhesive or an ultraviolet curing-type adhesive, and may be appropriately selected and used depending on the situation.

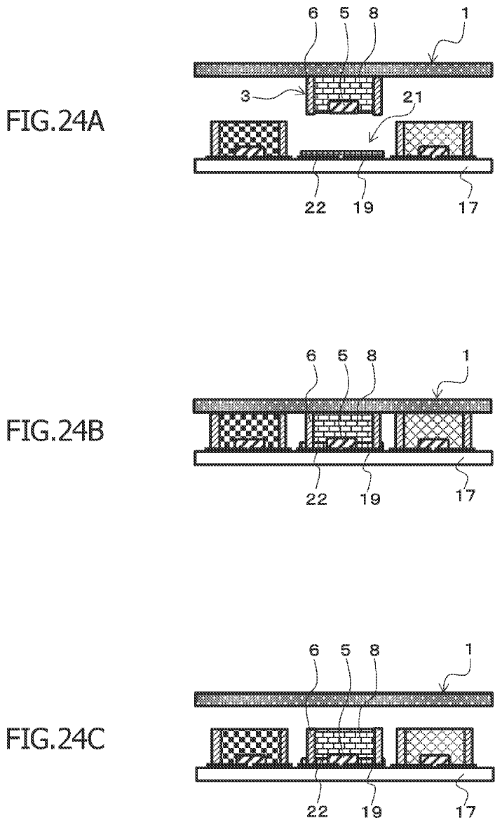

Next, as illustrated in FIG. 24A, one repair device 3 of the carrier film 1 is positioned on the defective pixel 21. In this case, the repair alignment marks 9A are provided on the transparent support film 2 of the carrier film 1 to correspond to the repair device 3 and the repair alignment marks 9B are provided to correspond to the defective pixel 21 on the wiring board 17 that is observed through the transmissive support film 2, and the repair alignment marks 9A and 9B are aligned to match each other or have a predetermined positional relationship.

Next, as illustrated in FIG. 24B, the repair device 3 is pressed against the wiring board 17 from the carrier film 1 side. As a result, the electrodes 15 of the LED 5 electrically contact the lead wiring 19 in the defective pixel 21, and the repair device 3 contacts the adhesive 22. Then, the wiring board 17 is energized in this state, and the lighting of the repair device 3 is inspected.

When the LED 5 is determined to be non-defective as a result of the lighting inspection, the adhesive 22 is heat-cured or UV-cured, and the repair device 3 is adhesively fixed to the defective pixel 21 while maintaining the electrical connection state between the electrodes 15 of the LED and the lead wiring 19.

Then, as illustrated in FIG. 24C, when the carrier film 1 is torn off from the wiring board 17, the carrier film 1 is peeled off from the device 3 due to difference in strength between the viscosity of the support film 2 of the carrier film 1 and the adhesive force of the adhesive, and the repair device 3 remains on the wiring board 17 to complete the repairing of the defective pixel 21.

In the above description, the carrier film 1 is the support film 2 onto which the gluing agent has been applied, and in order to peel the carrier film 1 off from the repair device 3, the difference in strength between the viscosity of the gluing agent and the adhesive force of the adhesive 22 to adhere the repair device 3 to the wiring board 17 is used. However, the present invention is not limited to this example, and the laser lift-off may be used. That is, the repair device 3 is joined to the support film 2 of the carrier film 1 through the adhesive, and when the carrier film 1 is peeled off from the repair device 3 that is joined to the wiring board 17, the laser beam L may be irradiated from the carrier film 1 side using, for example, the 266-nm picosecond laser to ablate the adhesive on the carrier film 1 side and peel off the carrier film 1.

Furthermore, although one defective pixel 21 is repaired in the above description, a row of pixels that includes defective pixels 21 may be simultaneously replaced. In this case, one row of pixels that includes defective pixels 21 may be removed from the full-color LED display panel and replaced with one row of repair devices 3 that is correspondingly provided on the carrier film 1.

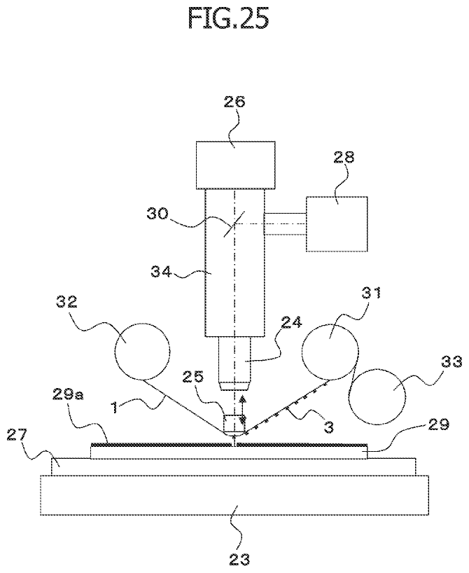

FIG. 25 is the front view illustrating the schematic configuration of an embodiment of the repair apparatus for repairing the LED display panel according to the present invention. The repair apparatus includes the stage 23, objective lens 24, carrier film 1, pressure head 25, observation camera 26, hot plate 27, and UV light source 28.

The stage 23 on which the full-color LED display panel 29 to be repaired is mounted moves in the two-dimensional plane that is parallel to the panel surface 29a of the full-color LED display panel 29, and rotates around the central axis that is perpendicular to the panel surface 29a.

The objective lens 24 is provided such that the optical axis is perpendicular to the mounting surface of the stage 23. The objective lens 24 is for magnifying and forming an image of the panel surface 29a of the full-color LED display panel 29 to be repaired which is mounted on the stage 23 onto the imaging surface of the observation camera 26, which will be described later. The objective lens 24 is also for focusing the ultraviolet light emitted from the UV light source 28, which will be described later, onto the defective pixel 21.

The carrier film 1 can move between the stage 23 and the objective lens 24. The carrier film 1 has the plurality of repair devices 3 arranged on the support film 2, each repair device 3 has the repair element in each opening 7 that is surrounded by the light shielding wall 6, the repair element is for repairing the defective pixel 21 on the full-color LED display panel 29 to be repaired, and the carrier film 1 is moved while the repair devices 3 face the stage 23.

The pressure head 25 is arranged between the objective lens 24 and the carrier film 1. The pressure head 25 is for pushing the carrier film 1 down to press the repair device 3 against the defective pixel 21 of the full-color LED display panel 29 to be repaired, and is made of transparent glass such as quartz glass. In particular, the side of the pressure head 25 which comes into contact with the carrier film 1 is formed to have an arc shape at least in the moving direction of the carrier film 1. The pressure head 25 moves vertically along the optical axis of the objective lens 24 by means of the moving mechanism (not illustrated).

The observation camera 26 is provided at one end of the optical path of the objective lens 24 which is opposite to the stage 23 side. The observation camera 26 is for observing the panel surface 29a, and is the CCD camera or CMOS camera, for example.

The optical path that runs from the objective lens 24 to the observation camera 26 is branched by the half mirror 30, and the UV light source 28 is provided at the branched end of the optical path. The UV light source 28 adheres the repair device 3 to the defective pixel 21 through the ultraviolet curing-type adhesive. The half mirror 30 includes the wavelength-selective reflective mirror that separates the UV light from the visible light. In the case as illustrated in FIG. 25, the wavelength-selective reflection mirror transmits the visible light and reflects the UV light.

FIG. 25 also illustrates the delivery reel 31 that holds and sends out the carrier film 1 that is wound in a roll shape, the take-up reel 32 that winds up the carrier film 1, the protective film winding reel 33 that winds up the protective film 4 of the carrier film 1, and the lens barrel 34 that includes the half mirror 30 and the like.

Next, repairing the LED display panel using such configured repair apparatus will be described.

First, the full-color LED display panel 29 to be repaired is placed on the hot plate 27 that is provided on the mounting surface of the stage 23. A defective pixel 21 is detected on the full-color LED display panel 29 to be repaired as a result of the lighting inspection performed in advance with the lighting inspection device. The position coordinates of the defective pixel 21 are stored in the control device (not illustrated).

Next, the stage 23 that is controlled by the control device moves parallel in the two-dimensional direction, and the defective pixel 21 on the full-color LED display panel 29 to be repaired is positioned within the field of view of the objective lens 24 based on the stored position coordinates of the defective pixel 21.

Next, the take-up reel 32 is driven to take up the carrier film 1 by a predetermined amount, and the repair device 3 of the carrier film 1 is positioned in the central field of view of the objective lens 24.

Next, the repair alignment marks 9A of the carrier film 1 and the repair alignment marks 9B that are provided on the wiring board 17 of the LED display panel 29 and observed through the transmissive carrier film 1 are detected by the observation camera 26 through the objective lens 24 and pressure head 25. The stage 23 is moved in parallel in the two-dimensional plane such that the repair alignment marks 9A and 9B match one another or have the predetermined positional relationship, and the stage 23 is rotated around the central axis that is perpendicular to the stage 23 to perform the alignment.

If the repair device 3 is made up of the light shielding wall 6 and the fluorescent layer 8, the alignment may include adjusting the repair device 3 to match the defective pixel 21 only.

When the alignment is complete, the pressure head 25 moves downward along the optical axis of the objective lens 24, and pushes the carrier film 1 down to press the repair device 3 against the defective pixel 21. Thus, the electrodes 15 of the LED 5 of the repair device 3 are in electrical contact with the lead wiring 19 of the defective pixel 21. In this case, the adhesive 22 is preliminarily applied to the defective pixel 21 excluding the lead wiring 19.

Subsequently, the wiring board 17 of the LED display panel is energized, and the lighting of the repair device 3 is inspected. Specifically, the lighting state of the repair device 3 is detected through the observation camera 26, and lighting failure, emission brightness and emission wavelength are inspected.

In this case, if the repair device 3 is determined to be non-defective, while maintaining the electrical contact between the electrodes 15 of the LED 5 of the repair device 3 and the lead wiring 19 of the defective pixel 21, the adhesive 22, in the case of the heat-curing type adhesive, is heat-cured by heating the hot plate 27. Alternatively, if the adhesive 22 is the ultraviolet curing-type adhesive, ultraviolet light is emitted from a UV light source 28, and the adhesive 22 is UV-cured. As a result, the repair device 3 is adhesively fixed to the wiring board 17.

Next, the pressure head 25 rises along the optical axis of the objective lens 24. At this time, tension is applied to the carrier film 1 along the moving direction, and thus, the upward force acts on the carrier film 1. Therefore, if the adhesive force of the adhesive 22 between the repair device 3 and the wiring board 17 is greater than the viscosity of the gluing agent between the carrier film 1 and the repair device 3, the carrier film 1 is peeled off from the repair device 3 to complete the repair process.

If the carrier film 1 and repair device 3 are adhered together by means of the adhesive instead of the gluing agent, the adhesive may be ablated by irradiating, for example, the UV laser beam L from the carrier film 1 side to perform laser lift-off of the repair device 3 from the carrier film 1. In this case, the UV light source 28 may be the laser light source and may be used for both the laser lift-off and UV curing.

Thereafter, if the second defective pixel 21 further exists, the same operation as described above is repeatedly performed to repair the second defective pixel 21.

In the above-described embodiment, the repair apparatus includes both the hot plate 27 and UV light source 28 for curing the adhesive 22; however, the present invention may have only one of them, depending on the adhesive 22 to be used.

### REFERENCE SYMBOL LIST

1 Carrier film
2 Support film
3 Repair device
4 Protective film
5, 5R, 5G, 5B LED (Repair element)
6 Light shielding wall
7 Opening
8, 8R, 8G, 8B Fluorescent layer (Repair element)
12 Photosensitive resin
13 Thin film
21 Defective pixel
23 Stage
24 Objective lens
25 Pressure head
26 Observation camera
27 Hot plate (Heating device)
28 UV light source

1. A carrier film comprising a plurality of repair devices that are arranged on a support film, and each of which has a repair element in an opening that is surrounded by a light shielding wall for repairing defective pixels on a full-color LED display panel.

2. The carrier film as claimed in claim 1, wherein the repair element is an LED of at least one of three primary color lights, and a light emitting surface of the LED is adhered to the support film.

3. The carrier film as claimed in claim 1, wherein each LED in the full-color LED display panel emits excitation light in an ultraviolet or blue wavelength band, each repair device has a fluorescent layer for each color in the opening that is surrounded by the light shielding wall, and the fluorescent layer which serves as the repair element is excited by the excitation light so as to emit light, and an end surface on one side of the fluorescent layer is adhered to the support film.

4. The carrier film as claimed in claim 1, wherein each LED in the full-color LED display panel emits excitation light in an ultraviolet or blue wavelength band, the repair device has an LED and a fluorescent layer for each color in the opening that is surrounded by the light shielding wall, in such a way that the fluorescent layer on the light emitting surface of the LED is excited by the excitation light so as to emit light, and an end surface opposite from the LED of the fluorescent layer is adhered to the support film.

5. The carrier film as claimed in any one of claims 1 to 4, wherein the support film includes a tape that has a long axis in one direction or a sheet spreading in two dimensions.

6. The carrier film as claimed in any one of claims 1 to 4, wherein the support film is an ultraviolet transmissive film.

7. The carrier film as claimed in any one of claims 1 to 4, wherein the support film is provided with convex portions that are taller than the repair devices, the convex portions are formed continuously or intermittently along both edges of the support film that are parallel to the arrangement direction of the repair devices.

8. The carrier film as claimed in any one of claims 1 to 4, wherein a protective film is provided opposite to the support film across the repair devices, and the protective film is adhesively provided in a manner that can be easily peeled off from the plurality of repair devices.

9. A method for repairing an LED display panel by using a carrier film to repair defective pixels, wherein the carrier film has a plurality of repair devices that are arranged on a support film, and each of which has a repair element in an opening surrounded by a light shielding wall for repairing the defective pixels on the full-color LED display panel, the method comprising the steps of:
a first step of removing a defective element corresponding to a defective pixel from the full-color LED display panel;
a second step of joining one of the repair devices on the carrier film to the defective pixel; and
a third step of peeling the support film off from the one of the repair devices that is joined to the defective pixel.

10. The method for repairing the LED display panel as claimed in claim 9, wherein the defective element is removed by laser irradiation in the first step.

11. The method for repairing the LED display panel as claimed in claim 10, wherein a wiring in the defective pixel is repaired by laser CVD after the defective element is removed in the first step.

12. The method for repairing the LED display panel as claimed in any one of claims 9 to 11, wherein the repair element is an LED, and a light emitting surface of the LED is adhesively supported by the support film.

13. The method for repairing the LED display panel as claimed in any one of claims 9 to 11, wherein each LED in the full-color LED display panel emits excitation light in an ultraviolet or blue wavelength band, and wherein the carrier film has a structure in which one end of the light shielding wall of the repair device adhesively supported by the support film, the repair device has a fluorescent layer as a repair element for each color in the opening that is surrounded by the light shielding wall, and the fluorescent layer is excited by the excitation light so as to emit light, further comprising:
electrically joining the LED for repair to the defective pixel from which the defective element is removed in the first step,
wherein in the second step, the repair device that has a fluorescent layer of corresponding color is joined to the defective pixel.

14. The method for repairing the LED display panel as claimed in any one of claims 9 to 11, wherein each LED in the full-color LED display panel emits excitation light in an ultraviolet or blue wavelength band, and wherein the carrier film has an end face opposite from the LED of the fluorescent layer of the repair device adhesively supported by the support film, in which the repair device has a structure in which the LED for repair and the fluorescent layer serving as a repair element for each color in the opening that is surrounded by the light shielding wall, and the fluorescent layer on the light emitting surface of the LED is excited by the excitation light so as to emit light, and
wherein the LED of the repair device that has a fluorescent layer of corresponding color is electrically joined to the defective pixel in the second step.

15. An apparatus for repairing an LED display panel, comprising:
a stage on which a full-color LED display panel to be repaired is mounted, wherein the stage moves in a two-dimensional plane that is parallel to a panel surface of the full-color LED display panel, and rotates around a central axis perpendicular to the panel surface;
an objective lens arranged such that an optical axis is perpendicular to the mounting surface of the stage;
a carrier film that includes a plurality of repair devices that are arranged on a support film, wherein each repair device has a repair element for repairing defective pixels on the full-color LED display panel to be repaired, the repair element is placed in an opening that is surrounded by a light shielding wall, and the carrier film is moved between the stage and the objective lens while the repair devices face the stage;
a transparent pressure head arranged between the objective lens and the carrier film, wherein the pressure head pushes down the carrier film to press one of the repair devices against the defective pixel on the full-color LED display panel to be repaired; and
an observation camera provided at one end opposite from the stage of the optical path passing through the objective lens for observing the panel surface.

16. The apparatus for repairing the LED display panel as claimed in claim 15, wherein the mounting surface of the stage is provided with a heating device for heating the full-color LED display panel to be repaired and adhering the one of the repair devices to the defective pixel through a heat-curable adhesive.

17. The apparatus for repairing the LED display panel as claimed in claim 15, wherein a light source for adhering the one of the repair devices to the defective pixel by an ultraviolet curable adhesive is provided at a branched end of the optical path that runs from the objective lens to the observation camera and that is branched by a half mirror.

18. The apparatus for repairing the LED display panel as claimed in claim 17, wherein the light source is a laser for emitting an ultraviolet light that enables joining the one of the repair devices to the defective pixel on the full-color LED display panel to be repaired, and that enables the support film of the carrier film to be peeled off from the one of the repair devices.
